(19) United States
(12) Patent Application Publication
(10) Pub. No.: US 2020/0158753 A1
(43) Pub. Date: May 21, 2020

(54) PROBE PIN

(71) Applicant: OMRON Corporation, Kyoto-shi, Kyoto (JP)

(72) Inventors: Hirotada TERANISHI, Osaka-shi (JP); Takahiro SAKAI, Moriyama-shi (JP)

(73) Assignee: OMRON Corporation, Kyoto-shi, Kyoto (JP)

(21) Appl. No.: 15/751,193

(22) PCT Filed: Mar. 14, 2017
(86) PCT No.: PCT/JP2017/010192

§ 371 Date: Feb. 8, 2018

(30) Foreign Application Priority Data
Jun. 17, 2016 (JP) 2016-121152

(51) Int. Cl. G01R 1/067; G09G 3/00

(52) U.S. Cl. CPC G01R 1/06722; G01R 1/06738; G09G 3/006

(57) ABSTRACT

A probe pin includes an elastic portion, a first contact portion having a pair of leg portions that extends from a first end of the elastic portion along a longitudinal direction and is bendable in a direction approaching each other, and that has a pair of contact portions each of which is disposed at each tip of the pair of leg portion and is urged by the elastic portion in a direction along the longitudinal direction through the pair of leg portions to be able to be brought into contact with a recessed contact of an inspection object, and a second contact portion that is disposed at a second end of the elastic portion and is electrically connected to the first contact portion, wherein a gap is provided between the pair of leg portion.

### TECHNICAL FIELD

The present invention relates to a probe pin.

### BACKGROUND ART

In an electronic component module such as a camera and a liquid crystal panel, a continuity inspection, an operating characteristic inspection, and the like are typically performed in its manufacturing process. These inspections each are performed by connecting an FPC contact electrode installed in the electronic component module to be connected to a main body substrate, or an electrode portion of amounted board-to-board connector or the like, to an inspection device by using a probe pin.

This kind of probe pin is described in PTL 1, for example. The probe pin is composed of an elastic portion that expands and contracts in its longitudinal direction and a contact portion that is provided at both ends in the longitudinal direction of the elastic portion.

### CITATION LIST

### Patent Literature

PTL 1: Japanese Unexamined Patent Publication No. 2008-516398

### SUMMARY OF INVENTION

### Technical Problem

Unfortunately, the probe pin is brought into contact with each of an inspection object and an inspection device at one contact portion, so that when a terminal of the inspection object is a recessed contact of a female connector of a board-to-board connector, or the like, for example, it is impossible to stably connect the contact portion of the probe pin to the recessed contact of the inspection object, and whereby contact reliability cannot be secured in some cases.

Thus, it is an object of the present invention to provide a probe pin capable of being stably connected to a recessed contact.

### Solution to Problem

A probe pin of an aspect of the present invention includes: an elastic portion that expands and contracts along its longitudinal direction; a first contact portion that has a pair of leg portions that extends from a first end of the elastic portion along the longitudinal direction and is bendable in a direction approaching each other, and that has a pair of contact portions each of which is disposed at each tip of the pair of leg portions while being urged by the elastic portion in a direction along the longitudinal direction through the pair of leg portions to be able to be brought into contact with a recessed contact of an inspection object; and a second contact portion that is disposed at a second end of the elastic portion and is urged by the elastic portion in a direction opposite to an urging direction of the first contact portion, and that is electrically connected to the first contact portion, wherein a gap is provided between the pair of leg portions.

### Advantageous Effects of Invention

According to the probe pin of the above aspect, the pair of contact portions of the pair of leg portions is brought into contact with the recessed contact while the pair of leg portions bends in a direction approaching the recessed contact, so that the probe pin can be stably connected to the recessed contact.

### BRIEF DESCRIPTION OF DRAWINGS

FIG. 1 is a perspective view for illustrating a use state of a probe pin according to an embodiment of the present invention.

FIG. 2 is a sectional view taken along line II-II of FIG. 1.

FIG. 3 is a perspective view of a probe pin according to an embodiment of the present invention.

FIG. 4 is a plan view of the probe pin of FIG. 3.

FIG. 5 is a sectional view illustrating a state before being brought into contact with a recessed contact of a female connector of the probe pin of FIG. 3.

FIG. 6 is a sectional view illustrating a state in contact with the recessed contact of the female connector of the probe pin of FIG. 3.

FIG. 7 is a plan view illustrating a first example of the probe pin of FIG. 3.

FIG. 8 is a plan view illustrating a second example of the probe pin of FIG. 3.

FIG. 9 is a sectional view illustrating a state in contact with a recessed contact of a female connector of the probe pin of FIG. 8.

FIG. 10 is a plan view illustrating a third example of the probe pin of FIG. 3.

FIG. 11 is a perspective view illustrating a fourth example of the probe pin of FIG. 3.

### DESCRIPTION OF EMBODIMENTS

Hereinafter, an embodiment of the present invention will be described with reference to accompanying drawings. In the following description, terms (e.g., terms including “upper”, “lower”, “right”, and “left”) each indicating a specific direction or position are used as necessary, and these terms are used to facilitate understanding of the invention with reference to the drawings, and the technical scope of the present invention is not limited by the meaning of these terms. In addition, the following description is merely intrinsically exemplary, and is not intended to limit the invention, its application, or its use. Further, the drawings are schematic, and a ratio of each dimension and the like do not necessarily coincide with actual ones.

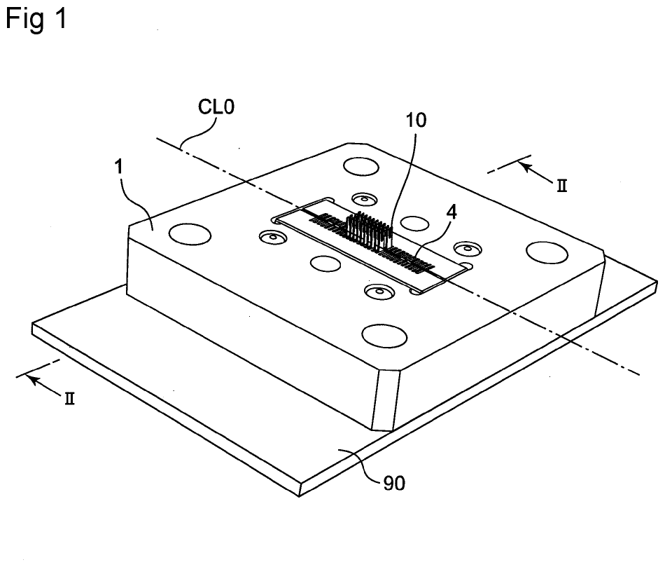

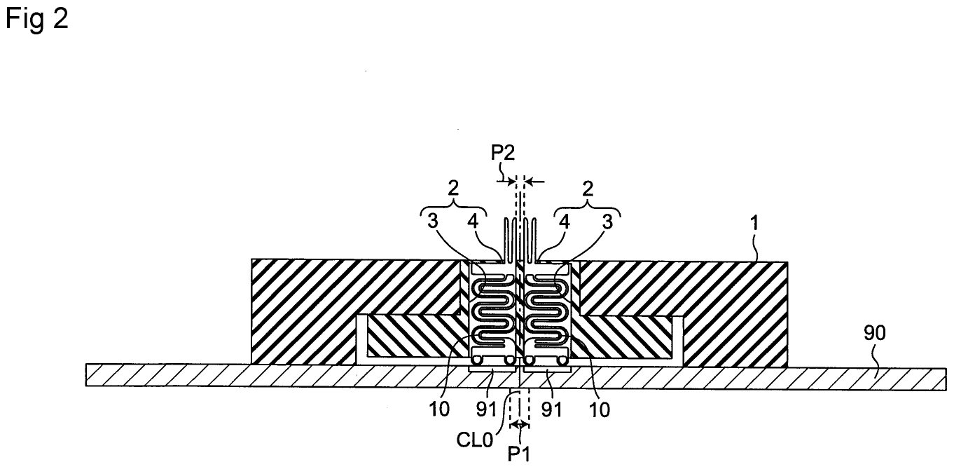

As illustrated in FIG. 1, for example, a probe pin 10 according to an embodiment of the present invention is used in a state of being housed in a socket 1 attached to a substrate 90 of an inspection apparatus, and constitutes an inspection unit together with the socket 1. As illustrated in FIG. 2, the socket 1 includes a plurality of pairs of housing portions 2 provided symmetrically with respect to a centerline CL0, and the probe pins 10 are housed in the respective housing portions 2.

Each of the housing portions 2 has a groove portion 3 capable of housing the probe pin 10, and a through hole 4 provided in a bottom surface of the groove portion 3, and the housing portions 2 are disposed at a regular interval along the centerline CL0 of the socket 1, as illustrated in FIG. 1.

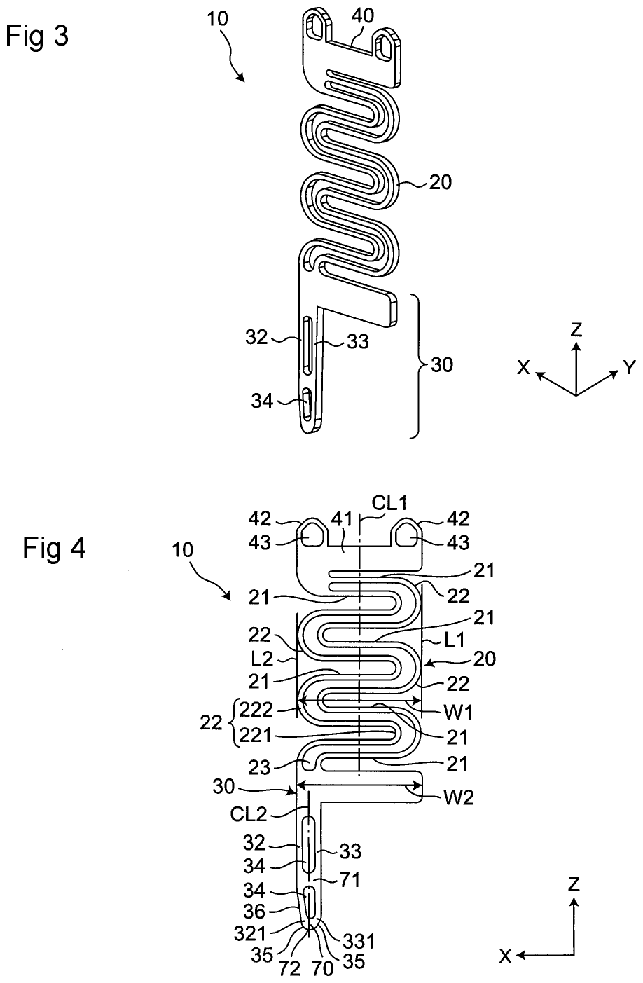

As illustrated in FIG. 3, the probe pin 10 includes an elastic portion 20, a first contact portion 30, and a second contact portion 40, the first and second contact portions 30 and 40 being provided at both respective ends in a longitudinal direction of the elastic portion 20. The probe pin 10 is a thin plate with conductivity, and is integrally formed by electroforming, for example.

In the following description, a width direction of a plate surface of the probe pin 10 is indicated as an X direction, a plate thickness direction of the probe pin 10, orthogonal to the X direction, is indicated as a Y direction, and the longitudinal direction of the elastic portion 20, orthogonal to the X and Y directions, is indicated as a Z direction.

As illustrated in FIG. 4, the elastic portion 20 has a serpentine shape in which straight portions 21 and curved portions 22 are alternately continuous along the Z direction, and is configured to expand and contract along the Z direction.

In a no-load state illustrated in FIG. 4, the straight portions 21 are parallel to each other in the X direction. The curved portions 22 each include a first curved portion 221 positioned on the right in the X direction, and a second curved portion 222 positioned on the left in the X direction. Then, a straight line L1 connecting vertexes of the respective first curved portions 221 adjacent to each other, and a straight line L2 connecting vertexes of the respective second curved portions 222 adjacent to each other, are parallel to each other in the X direction.

In addition, a through hole 23 passing through in the plate thickness direction (Y direction) and extending along the serpentine shape is provided in an intermediate portion in the width direction of each of the straight portions 21 of the elastic portion 20 and in an intermediate portion in the width direction of each of the curved portions 22. This enhances elasticity of the elastic portion 20.

As illustrated in FIG. 4, the first contact portion 30 includes a support portion 31 that is connected to a lower end of the elastic portion 20 in the Z direction, a pair of leg portions 32 and 33 that is bendable and extends downward in the Z direction from the support portion 31, and a pair of contact portions 321 and 331 each of which is disposed at each tip of the pair of leg portions 32 and 33 so as to be able to be brought into contact with a recessed contact of an inspection object. The pair of contact portions 321 and 331 is connected by a contact connecting portion 70, and can be urged downward in the Z direction by the elastic portion 20 via the pair of leg portions 32 and 33.

The support portion 31 has a substantially rectangular shape in plan view along the Y direction, and supports the probe pin 10 by being brought into contact with the groove portion 3 of the housing portion 2 when the probe pin 10 is housed in the housing portion 2 of the socket 1. The support portion 31 has a width W2 that is approximately the same as a width W1 that is the shortest distance between a straight line L1 being a tangent line connecting the second curved portions 222 adjacent to each other in the longitudinal direction of the elastic portion 20, and a straight line L2 being a tangent line connecting the first curved portions 221 adjacent to each other in the longitudinal direction of the elastic portion 20.

The support portion 31 is connected on its left side in the X direction and on its upper side in the Z direction to a lower end of the elastic portion 20 in the Z direction. In addition, the support portion 31 is connected on its left side in the X direction and on its lower side in the Z direction to the pair of leg portions 32 and 33. That is, a centerline CL1 of the X direction extending in the Z direction of the elastic portion 20 and a centerline CL2 of the X direction extending in the Z direction of the pair of leg portions 32 and 33 do not coincide with each other, and are displaced from each other. In other words, the elastic portion 20 and the pair of leg portions 32 and 33 are connected to each other via one end of the support portion 31 in the X direction away from the centerline CL1 of the X direction extending in the Z direction of the elastic portion 20.

Each of the pair of leg portions 32 and 33 extends in the Z direction and is provided asymmetrically with respect to the centerline CL2 of the X direction. The pair of leg portions 32 and 33 is provided with a gap 34 therebetween, the gap 34 being deformable in a direction in which the leg portions 32 and 33 approach each other. The pair of leg portions 32 and is connected by a leg connecting portion 71. The leg connecting portion 71 is provided at the boundary between the pair of leg portions 32 and 33, and the pair of contact portions 321 and 331 to divide the gap 34 into two in the Z direction. The gap 34 on a side (upper side in the Z direction) of the pair of leg portions 32 and 33 can adjust an orientation of the pair of leg portions 32 and 33, so that it is possible to adjust positional displacement between the pair of contact portions 321 and 331, and the recessed contact, when the pair of leg portions 32 and 33 is brought into contact with the recessed contact, for example.

In addition, each of the pair of leg portions 32 and 33 is bendable in a direction approaching the centerline CL2 of the pair of leg portions 32 and 33 in the X direction (or a direction approaching each other). That is, the leg portion 32 on the left side in the X direction is bendable toward the right side in the X direction, and the leg portion 33 on the right side in the X direction is bendable toward the left side in the X direction. In other words, when the pair of leg portions 32 and 33 is inserted into a recessed contact of an inspection object, each of the pair of contact portions 321 and 331 provided at the each tip of the pair of leg portions 32 and 33 can slide in a direction approaching each other while being in contact with the recessed contact.

Each of the pair of contact portions 321 and 331 at the each tip (the lower end in the Z direction) of the pair of leg portions 32 and 33 is provided with curved surfaces 35 that can be brought into contact with a recessed contact. The curved surfaces 35 of the pair of respective contact portions 321 and 331 are integrated via a contact connecting portion 70. That is, the contact connecting portion 70 has a curved surface 72 continuous with the curved surfaces 35 of the pair of respective contact portions 321 and 331, and connects the pair of leg portions 32 and 33 to each other in a frame shape.

Further, an outer surface of the contact portion 321 on the left side in the X direction, the outer surface of the contact portion 321 being opposite to an inner surface of the contact portion 321 on the left in the X direction and the inner surface of the contact portion 321 facing the contact portion 331 on the right in the X direction, includes an inclined surface 36 of a flat surface or a curved-inward surface, approaching the other of outer surfaces in an urging direction of the elastic portion 20, or downward in the Z direction.

The second contact portion 40 includes a base portion 41 connected to an upper end of the elastic portion 20 in the Z direction, and a pair of projecting portions 42 protruding upward in the Z direction from the base portion 41 The second contact portion 40 is electrically connected to the first contact portion 30. The second contact portion 40 is urged upward in the Z direction by the elastic portion 20, or in a direction opposite to an urging direction of the first contact portion 30.

The base portion 41 has a substantially rectangular shape in plan view along the Y direction. The base portion 41 is connected on its left side in the X direction and on its lower side in the Z direction to an upper end of the elastic portion 20 in the Z direction.

The pair of projecting portions 42 are provided symmetrically with respect to the centerline CIA of the elastic portion 20 in the X direction. Each of the projecting portions 42 is curved such that its tip (upper end in the Z direction) protrudes upward in the Z direction to be brought into contact with a terminal 91 (illustrated in FIG. 2) provided on the substrate 90 of the inspection device while being housed in the socket 1.

In addition, each of the projecting portions 42 is provided with a through hole 43 passing through in the plate thickness direction (Y direction). As a result, each of the projecting portions 42 elastically deforms when being brought into contact with the terminal 91 of the substrate 90 to press the terminal 91 by its elastic force, so that contact reliability between the probe pin 10 and the inspection device can be enhanced.

When each of the projecting portions 42 is provided at both respective ends of the base portion 41, it is possible to reduce a pitch P1 between the projecting portions 42 of the probe pins 10 adjacent to each other in the Y direction when the probe pins 10 are housed in the socket 1, as illustrated in FIG. 2. In addition, forming of the projecting portions 42 enables stable contact with the substrate 90 of the inspection device.

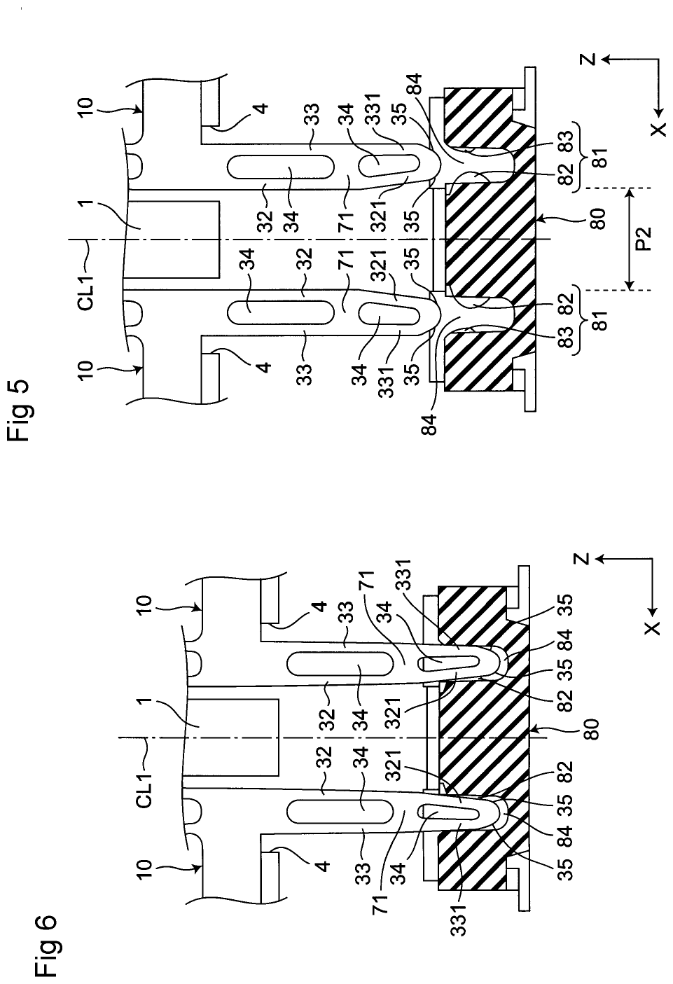

Next, with reference to FIGS. 5 and 6, there is described operation in the case where two probe pins 10 are brought into contact with two respective adjacent recessed contacts 81 of an inspection object 80 while being housed in the housing portions 2 of the socket 1. The recessed contact 81 is provided with a pair of contact portions 82 and 83 facing each other in a direction (X direction) intersecting an insertion direction (Z direction) of the probe pin 10 in mutually facing surfaces in the recessed portion of the inspection object 80. The pair of contact portions 82 and 83 is provided with a deformable gap 84 therebetween.

As illustrated in FIG. 5, when each of the probe pins 10 are brought close to the inspection object 80 while each of the pair of leg portions 32 and 33 of the probe pins 10 is positioned in the gap 84 between the pair of contact portions 82 and 83 of the recessed contact 81, outer surfaces of the curved surfaces 35 of the respective pair of contact portions 321 and 331 of the leg portions 32 and 33 are brought into contact with the pair of contact portions 82 and 83 of the recessed contact 81.

As each of the probe pins 10 is brought closer to the inspection object 80 and the leg portions 32 and 33 of each of the probe pins 10 is inserted into the gap 84 between the contact portions 82 and 83 of each recessed contact 81 of the inspection object 80, as illustrated in FIG. 6, the of leg portions 32 and 33 pushes out the contact portions 82 and 83 of the recessed contact 81 in a direction away from each other. Then, the contact portions 82 and 83 thus pushed out bends the leg portions 32 and 33 in a direction in which the leg portions 32 and 33 approach each other. At this time, the leg portions 32 and 33 moves while sliding in a state where the outer surfaces thereof are in contact with the contact portions 82 and 83.

Meanwhile, as each of the probe pins 10 is separated from the inspection object 80 and the leg portions 32 and 33 is pulled out from the gap 84 of the recessed contact 81 of the inspection object 80, the contact portions 82 and 83 of the recessed contact 81 returns in a direction in which they approach each other, and the leg portions 32 and 33 returns in a direction away from each other. At this time, the leg portions 32 and 33 moves while sliding in a state where the outer surfaces thereof are in contact with the contact portions 82 and 83 of the recessed contact 81.

As described above, in the probe pin 10 according to the embodiment, when the probe pin 10 is inserted into and pulled out from the inspection object 80, the pair of leg portions 32 and 33 moves while sliding or wiping in a state where the leg portions 32 and 33 is in contact with the contact portions 82 and 83 of the recessed contact 81, respectively. Thus, even when foreign matter adheres to a pair of outer surfaces of the contact portions 321 and 331 of the leg portions 32 and 33, or surfaces of the contact portions 82 and 83 of the recessed contact 81, the foreign matter is scraped by wiping between the contact portions 321 and 331 of the leg portions 32 and 33 and the contact portions 82 and 83 of the recessed contact 81. As a result, poor conduction due to foreign matter can be avoided to enable contact reliability to be secured.

The leg portions 32 and 33 is bendable in a direction approaching each other, and the gap 34 deformable in a direction in which the leg portions 32 and 33 approach each other is provided between the leg portions 32 and 33. This enables the contact portions 321 and 331 of the leg portions 32 and 33 to move more distance while being in contact with the pair of contact portions 82 and 83 of the recessed contact 81, so that wiping effect can be enhanced.

In addition, the first contact portion 30 includes the leg connecting portion 71 connecting the pair of leg portions 32 and 33 to each other. The amount of bend of the pair of leg portions 32 and 33 can be adjusted by adjusting a position of the leg connecting portion 71.

Further, the first contact portion 30 includes the contact connecting portion 70 that connects the pair of contact portions 321 and 331 of the leg portions 32 and 33 to each other. This integrates the pair of contact portions 321 and 331 with each other to facilitate insertion of the pair of leg portions 32 and 33 into the gap 84 of the recessed contact 81 of the inspection object 80.

Further, the centerline CL1 extending in the Z direction (longitudinal direction) of the elastic portion 20 and the centerline CL2 extending in the Z direction of the pair of leg portions 32 and 33 do not coincide with each other, and are displaced from each other. Thus, because the leg portions 32 and 33 is disposed in an end portion of the support portion 31 of each of the two probe pins 10 on a side where the two probe pins 10 are close to each other, when the two probe pins 10 are housed in the housing portions 2 of the socket 1, it is possible to deal with a narrow pitch in which a pitch between the two adjacent recessed contacts 81 of the inspection object 80 is narrowed, in comparison with a state where the leg portions 32 and 33 is disposed so that the centerline CL2 coincides with the centerline CL1 of the elastic portion 20.

Each of the pair of contact portions 321 and 331 at the each tip of the leg portions 32 and 33 is provided with the respective curved surfaces 35, and one of outer surfaces of the leg portions 32 and 33 includes the inclined surface 36 of a flat surface or a curved-inward surface, approaching the other of the outer surfaces toward an urging direction of the elastic portion 20. This enables the leg portions 32 and 33 to be smoothly guided to the gap 84 of the recessed contact 81 of the inspection object 80.

When the probe pin 10 has the gap 34 that is deformable in a direction approaching each other between the pair of contact portions 321 and 331 of the leg portions 32 and 33 that is bendable in a direction approaching each other, stable contact can be maintained.

For example, the leg portions 32 and 33 is not limited to structure in which both of them are bendable, and at least one of them may be bendable.

The curved surface 35 and the inclined surface 36 of each of the leg portions 32 and 33 may be eliminated, or may be provided in any one or both of the leg portions 32 and 33. Only the curved surface 35 may be provided, or only the inclined surface 36 may be provided. However, it is preferable to dispose the curved surface 35 or the inclined surface 36 to secure more stable contact with the recessed contact 81.

When there is no need to deal with a narrow pitch, the probe pin 10 may be formed such that the centerline CL1 extending in the Z direction of the elastic portion 20 coincides with the centerline CL2 extending in the Z direction of the pair of leg portions 32 and 33.

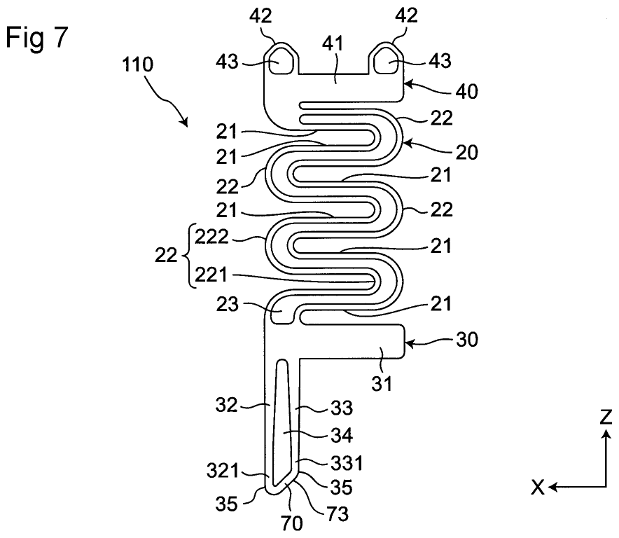

The contact connecting portion 70 may be configured to have an inclined surface 73 continuous with the curved surfaces 35 of the contact portions 321 and 331, instead of the curved surface 72, as illustrated in FIG. 7, for example. The gap 34 between the leg portions 32 and 33 is not limited to the case of being divided, and may be integrated by eliminating the leg connecting portion 71, as illustrated in FIG. 7.

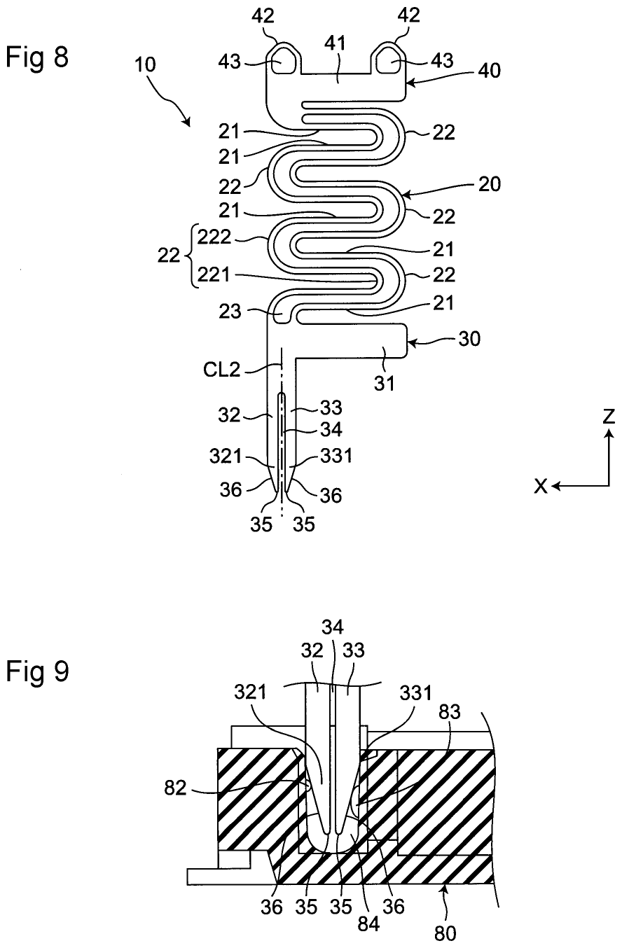

In addition, the contact connecting portion 70 can be eliminated, as illustrated in FIGS. 8 and 9. In this case, when the inclined surface 36 is provided in each of the outer surfaces of the contact portions 321 and 331, for example, insertion of the leg portions 32 and 33 into the gap 84 of the recessed contact 81 of the inspection object 80 can be facilitated.

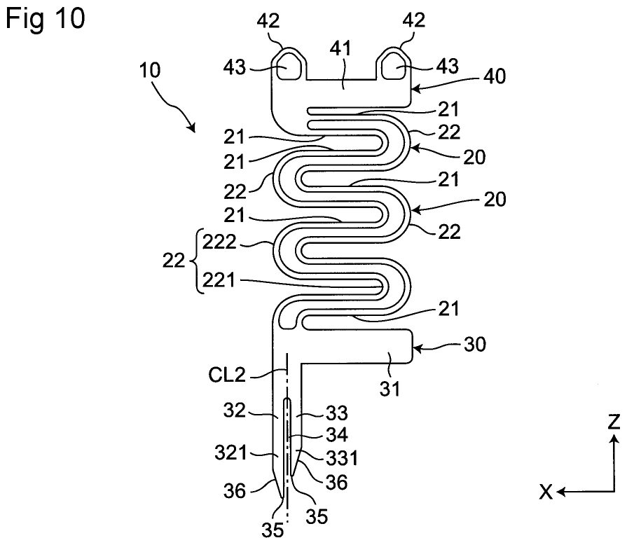

As illustrated in FIGS. 8 and 9, the leg portions 32 and 33 may be provided symmetrically with respect to the centerline CL2 extending in the longitudinal direction, or may be provided to be different from each other in length in its longitudinal direction, as illustrated in FIG. 10.

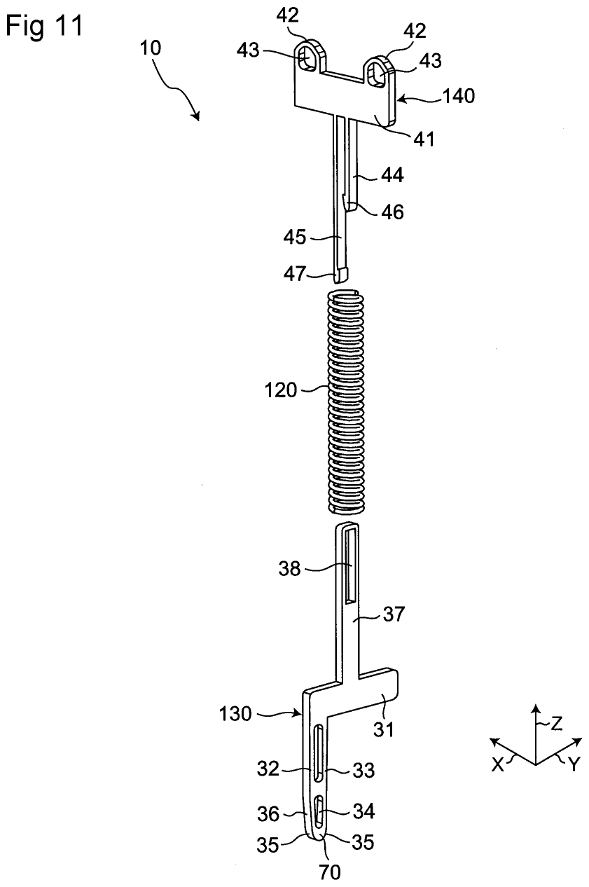

The probe pin 10 is not limited to the structure in which the elastic portion 20, and the first and second contact portions 30 and 40 are integrally formed. For example, as illustrated in FIG. 11, a first contact portion 130 and a second contact portion 140 may be formed separately.

In this case, the first contact portion 130 and the second contact portion 140 are partially positioned inside a coil spring 120 as an elastic body, and are connected to each other such that their plate surfaces are orthogonal to each other. In FIG. 7, a direction along the plate surface of the first contact portion 130 is indicated as a Y direction, a direction along the plate surface of the second contact portion 140 is indicated as an X direction, and a direction orthogonal to the X direction and the Y direction is indicated as a Z direction.

The first contact portion 130 extends upward in the Z direction from the support portion 31, and has an insertion portion 37 disposed inside the coil spring 120. The insertion portion 37 is provided with a through hole 38 passing through in the plate thickness direction (X direction) and extending along the Z direction.

The second contact portion 140 extends downward in the Z direction from the base portion 41, and has a pair of elastic pieces 44 and 45 disposed inside the coil spring 120. The pair of elastic pieces 44 and 45 is provided with a gap therebetween, the gap being larger than a plate thickness of the first contact portion 130. The one elastic piece 44 is provided at its tip with a protrusion 46 that can be fitted into the through hole 38 of the first contact portion 130. When the protrusion 46 is fitted into the through hole 38, the first contact portion 130 and the second contact portion 140 are connected to each other. The other elastic piece 45 is provided at its tip with a protrusion 47 that is brought into contact with a surface between the through hole 38 of the insertion portion 37 of the first contact portion 130 and the support portion 31 when the first contact portion 130 and the second contact portion 140 are connected to each other.

The coil spring 120 is supported at its both ends with the support portion 31 of the first contact portion 130 and the base portion 41 of the second contact portion 140, respectively, in a state where the first contact portion 130 and the second contact portion 140 are connected to each other, and thus the coil spring 120 is always compressed.

While various embodiments of the present invention have been described in detail with reference to the drawings, finally, various aspects of the present invention will be described.

A probe pin according to a first aspect of the present invention includes: an elastic portion that expands and contracts along its longitudinal direction; a first contact portion that has a pair of leg portions that extends from one end of the elastic portion along the longitudinal direction and is bendable in a direction approaching each other, and that has a pair of contact portions each of which is disposed at each tip of the pair of leg portions while being urged by the elastic portion in a direction along the longitudinal direction through the pair of leg portions to be able to be brought into contact with a recessed contact of an inspection object; and a second contact portion that is disposed at the other end of the elastic portion and is urged by the elastic portion in a direction opposite to an urging direction of the first contact portion, and that is electrically connected to the first contact portion, wherein a gap is provided between the pair of leg portions.

According to the probe pin of the first aspect, the pair of contact portions is brought into contact with the recessed contact while the pair of leg portions bends freely in a direction approaching each other with respect to the recessed contact, so that the probe pin can be stably connected to the recessed contact. In addition, the pair of contact portions of the leg portions moves while sliding in a state in contact with the recessed contact, so that wiping effect enables conduction failure, due to foreign matter attached to the surfaces of the pair of contact portions of the leg portions and the surfaces of the recessed contact, to be avoided.

In a probe pin according to a second aspect of the present invention, the probe pin further includes a contact connecting portion that connects the pair of contact portions of the leg portions to each other.

According to the probe pin of the second aspect, the pair of contact portions are integrated to facilitate insertion of the pair of leg portions into the recessed contact of the inspection object.

In a probe pin according to a third aspect of the present invention, the first contact portion includes a leg connecting portion provided at a boundary between the pair of leg portions and the pair of contact portions to connect the pair of leg portions.

According to the probe pin of the third aspect, the amount of bend of the pair of leg portions can be adjusted by adjusting a position of the leg connecting portion.

In a probe pin according to a fourth aspect of the present invention, a centerline along the longitudinal direction of the pair of leg portions and a centerline along a longitudinal direction of the elastic portion are displaced from each other.

According to the probe pin of the fourth aspect, the leg portions is disposed such that its centerline along its longitudinal direction and a centerline of the elastic portion along its longitudinal direction do not coincide with each other to be displaced from each other. Thus, it is possible to deal with a narrow pitch in which a pitch between two adjacent recessed contacts of the inspection object is narrowed, in comparison with a state where the leg portions is disposed such that its centerline along its longitudinal direction coincides with the centerline of the elastic portion along its longitudinal direction.

In a probe pin according to a fifth aspect of the present invention, each of the pair of contact portions of the leg portions of the first contact portion has a curved surface.

According to the probe pin of the fifth aspect, the pair of leg portions can be smoothly guided to the recessed contact.

In a probe pin according to a sixth aspect of the present invention, at least one of surfaces opposite to mutually facing surfaces of the pair of contact portions of the leg portions of the first contact portion includes an inclined surface approaching the other of the surfaces opposite to the mutually facing surfaces toward an urging direction of the elastic portion.

According to the probe pin of the sixth aspect, the pair of leg portions can be smoothly guided to the recessed contact.

When any embodiments or modifications of the various embodiments or modifications are suitably combined with each other, it is possible to achieve respective effects possessed by them. In addition, combinations of embodiments themselves or examples themselves, or combinations of embodiments and examples, are possible, and combinations of features in different embodiments or examples are also possible.

While the present invention is fully described in association with the preferred embodiments with reference to the accompanying drawings, various variations and modifications are obvious to those skilled in the art. Such variations and modifications should be understood to be included in the scope of the present invention according to the appended claims unless without departing from the scope thereof.

### INDUSTRIAL APPLICABILITY

The probe pin of the present invention can be applied to an inspection unit used for inspecting a liquid crystal panel having a female connector as a terminal, for example.

### REFERENCE SIGNS LIST

1. socket
2. housing portion
3. groove portion
4. through hole
10. probe pin
20. elastic portion
120. coil spring
21. straight portion
22. curved portion
23. through hole
221. first curved portion
222. second curved portion
30, 130. first contact portion
31. support portion
32, 33, 132, 133. leg portion
321, 331. contact portion
34. gap
35. curved surface
36. inclined surface
37. insertion portion
38. through hole
40, 140. second contact portion
41. base portion
42. projecting portion
43. through hole
44, 45. elastic piece
46, 47. protrusion
70. contact connecting portion
71. leg connecting portion
72. curved surface
73. inclined surface
80. inspection object
81. recessed contact
82, 83. contact portion
84. gap
90. substrate
91. terminal
CL0. centerline (of socket)
CL1. centerline (of elastic portion)
CL2. centerline (of pair of legs)
L1. straight line (connecting vertexes of first curved portion)
L2. straight line (connecting vertexes of second curved portion)
W1. width of elastic portion
W2. width of support portion
P1. pitch (between projecting portion of adjacent probe pins)
P2. pitch (between leg portions of adjacent probe pins)

1. A probe pin comprising:
an elastic portion that expands and contracts along its longitudinal direction;
a first contact portion that has a pair of leg portions that extends from a first end of the elastic portion along the longitudinal direction and is bendable in a direction approaching each other, and that has a pair of contact portions each of which is disposed at each tip of the pair of leg portions while being urged by the elastic portion in a direction along the longitudinal direction through the pair of leg portions to be able to be brought into contact with a recessed contact of an inspection object; and
a second contact portion that is disposed at a second end of the elastic portion and is urged by the elastic portion in a direction opposite to an urging direction of the first contact portion, and that is electrically connected to the first contact portion,
wherein a gap is provided between the pair of leg portions.

2. The probe pin according to claim 1, wherein
the first contact portion includes a contact connecting portion that connects the pair of contact portions of the pair of respective leg portions.

3. The probe pin according to claim 1, wherein
the first contact portion includes a leg connecting portion provided at a boundary between the pair of leg portions and the pair of contact portions to connect the pair of leg portions.

4. The probe pin according to claim 1, wherein
a centerline along a longitudinal direction of the pair of leg portions and a centerline along the longitudinal direction of the elastic portion are displaced from each other.

5. The probe pin according to claim 1, wherein
each of the pair of contact portions of the pair of leg portions of the first contact portion has a curved surface.

6. The probe pin according to claim 1, wherein
at least one of surfaces opposite to mutually facing surfaces of the pair of contact portions of the pair of leg portions of the first contact portion includes an inclined surface approaching an another one of the surfaces opposite to the mutually facing surfaces toward an urging direction of the elastic portion.
